(19) United States
(12) Patent Application Publication
(10) Pub. No.: US 2025/0351603 A1
(43) Pub. Date: Nov. 13, 2025

(54) IMAGE SENSOR

(71) Applicant: SAMSUNG ELECTRONICS CO., LTD., Suwon-si (KR)

(72) Inventors: Gyeonghoon Wang, Suwon-si (KR); Dongkyun Ahn, Suwon-si (KR); Jaehyung Song, Suwon-si (KR); Donghyun Yu, Suwon-si (KR)

(21) Appl. No.: 19/088,288

(22) Filed: Mar. 24, 2025

(30) Foreign Application Priority Data
May 13, 2024 (KR) 10-2024-0062728

(51) Int. Cl. H10F 39/00

(52) U.S. Cl. CPC H10F 39/807; H10F 39/8053

(57) ABSTRACT

An image sensor includes a substrate having pixel regions, and a deep isolation pattern provided between the pixel regions within the substrate, wherein the deep isolation pattern includes a liner film covering a sidewall of a trench in the substrate, a first pattern provided on an inner sidewall of the liner film and having a height less than a height of the liner film, an isolation film on inner sidewall of the first pattern, and a second pattern covering inner sidewalls of the isolation film and an upper portion of an inner sidewall of the liner film, a void is provided in the second pattern, the second pattern is spaced apart from the first pattern by the isolation film, and a grain size of the second pattern is larger than a grain size of the first pattern.

### CROSS-REFERENCE TO RELATED APPLICATION

This application is based on and claims priority under 35 U.S.C. §119 to Korean Patent Application No. 10-2024-0062728, filed on May 13, 2024, in the Korean Intellectual Property Office, the disclosure of which is incorporated by reference herein in its entirety.

### BACKGROUND

An image sensor is a device that converts optical images into electrical signals. Image sensors may be classified into a charge coupled device (CCD) type image sensor and a complementary metal oxide semiconductor (CMOS) type image sensor. The CMOS type image sensor is abbreviated as a CMOS image sensor (CIS). The CIS includes a plurality of pixels arranged two-dimensionally. Each pixel includes a photodiode (PD). The PD converts incident light into an electrical signal.

### SUMMARY

In some implementations, the disclosed image sensor has improved image characteristics and intensity compared to a conventional image sensor.

The objects to be achieved by the inventive concept are not limited to the technical objects described above and other objects that are not stated herein will be clearly understood by those skilled in the art from the following specifications.

In a first general aspect, an image sensor includes: a substrate having pixel regions, and a deep isolation pattern provided between the pixel regions within the substrate, wherein the deep isolation pattern includes a liner film covering a sidewall of a trench in the substrate, a first pattern provided on an inner sidewall of the liner film and having a height less than a height of the liner film, an isolation film on inner sidewall of the first pattern, and a second pattern covering inner sidewalls of the isolation film and an upper portion of an inner sidewall of the liner film, a void is provided in the second pattern, the second pattern is spaced apart from the first pattern by the isolation film, and a grain size of the second pattern is larger than a grain size of the first pattern.

In a second general aspect, an image sensor includes: a substrate having a first surface and a second surface that face each other, and a deep isolation pattern defining pixel regions in the substrate, wherein the deep isolation pattern includes a liner film covering a sidewall of a trench in the substrate, a first pattern on an inner sidewall of the liner film, a second pattern provided on the first pattern, and an isolation film between the first pattern and the second pattern, the second pattern is spaced apart from the first pattern by the isolation film, the isolation film includes a material different from that of the first pattern, and a first additional element provided in the isolation film includes a same element as a first dopant in the first pattern.

In a third general aspect, an image sensor includes: a substrate having a first surface, a second surface facing the first surface, and a plurality of pixel regions, photoelectric conversion regions provided between the first surface and the second surface of the substrate, a deep isolation pattern provided within the substrate and between the photoelectric conversion regions, impurity regions located within the substrate and located adjacent to the first surface of the substrate, a gate pattern disposed on the first surface of the substrate, a wiring layer disposed on the first surface of the substrate and including insulating layers and a conductive structure, color filters disposed on the second surface of the substrate, a grid pattern located between the color filters, and a microlens pattern disposed on the color filters, wherein the deep isolation pattern includes a liner film covering a sidewall of a trench in the substrate, a first pattern provided on an inner sidewall of the liner film and having a height less than a height of the liner film, an isolation film on inner sidewall of the first pattern, and a second pattern covering inner sidewalls of the isolation film and an upper portion of an inner sidewall of the liner film, a void is provided in the second pattern, the second pattern is spaced apart from the first pattern by the isolation film, the isolation film includes a material different from those of the first pattern and the second pattern, and a first additional element provided in the isolation film includes a same element as a first dopant in the first pattern.

### BRIEF DESCRIPTION OF THE DRAWINGS

FIG. 1 is a circuit diagram of an example of a pixel of an image sensor.

FIG. 2A is a diagram of an example of a pixel array region of an image sensor.

FIG. 2B is a cross-sectional view taken along a line I-I′ of FIG. 2A.

FIG. 2C is an enlarged view of a region III of FIG. 2B.

FIG. 2D is an enlarged view of a region IV of FIG. 2C.

FIG. 2E is an enlarged cross-sectional view showing an example of a deep isolation pattern in a cross section taken along a line II-II′ of FIG. 2A.

FIG. 3 is a diagram of an example of a deep isolation pattern.

FIG. 4A is a cross-sectional view of an example of an image sensor.

FIG. 4B is an enlarged view of a region III of FIG. 4A.

FIG. 4C is a diagram of an example of a deep isolation pattern.

FIG. 4D is a diagram of an example of a deep isolation pattern.

FIG. 5A is a plan view depicting an example of an arrangement of color filters of an image sensor.

FIG. 5B is a plan view depicting an example of an arrangement of color filters of an image sensor.

FIG. 5C is a cross-sectional view taken along a line I″-I′″ of FIG. 5B.

FIG. 5D is a plan view depicting an example of an arrangement of color filters of an image sensor.

FIGS. 6A to 6K are diagrams of an example of a method of manufacturing an image sensor.

In this specification, the same reference numerals may refer to the same elements throughout.

### DETAILED DESCRIPTION

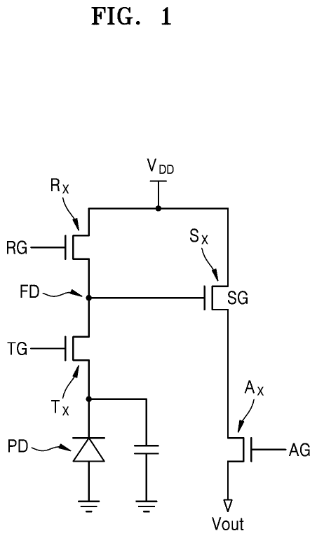

FIG. 1 is a circuit diagram of an example of a pixel of an image sensor.

Referring to FIG. 1, each pixel of the image sensor includes a photoelectric conversion region PD, a transfer transistor Tx, a source follower transistor Sx, a reset transistor Rx, and a selection transistor Ax. The transfer transistor Tx, the source follower transistor Sx, the reset transistor Rx, and the selection transistor Ax may each include a transfer gate TG, a source follower gate SG, a reset gate RG, and a selection gate AG.

The photoelectric conversion region PD may include a photodiode including an n-type impurity region and a p-type impurity region. A floating diffusion region FD may function as a drain of the transfer transistor TX. The floating diffusion region FD may function as a source of the reset transistor Rx. The floating diffusion region FD may be electrically connected to the source follower gate SG of the source follower transistor Sx. The source follower transistor Sx is connected to the selection transistor Ax.

An operation of the image sensor will be described below with reference to FIG. 1. First, in a state in which light is blocked, a power voltage V_{DD} is applied to the drain of the reset transistor Rx and the drain of the source follower transistor Sx, and the reset transistor Rx is turned on to discharge charges remaining in the floating diffusion region FD. Then, when the reset transistor Rx is turned off and external light is incident on the photoelectric conversion region PD, an electron-hole pair is generated in the photoelectric conversion region PD. Holes move to the p-type impurity region of the photoelectric conversion region PD, and electrons move to and accumulate in the n-type impurity region. When the transfer transistor Tx is turned on, charges such as electrons and holes are transferred to the floating diffusion region FD and accumulated. A gate bias of the source follower transistor Sx changes in proportion to the accumulated charge, resulting in a change in a source potential of the source follower transistor Sx. In this case, when the selection transistor Ax is turned on, a signal due to the charge is read through a column line.

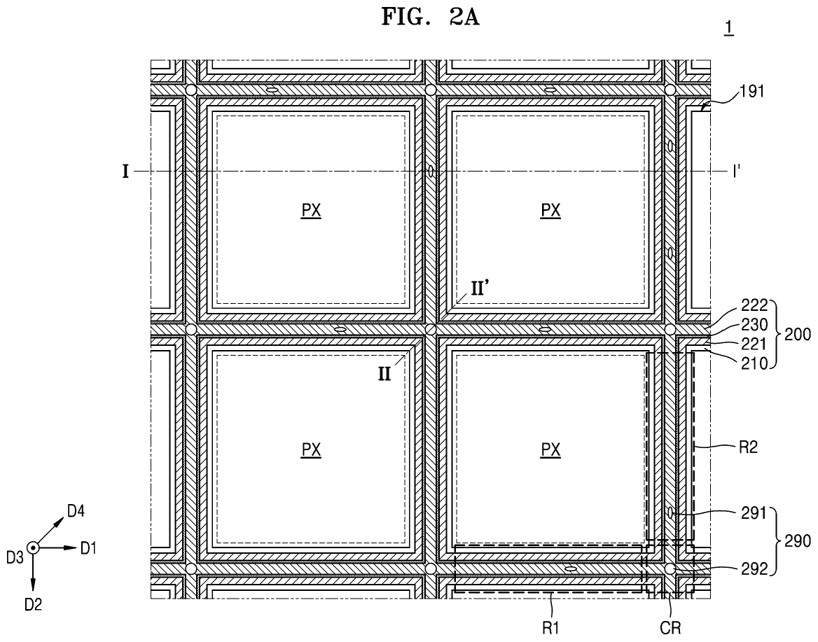

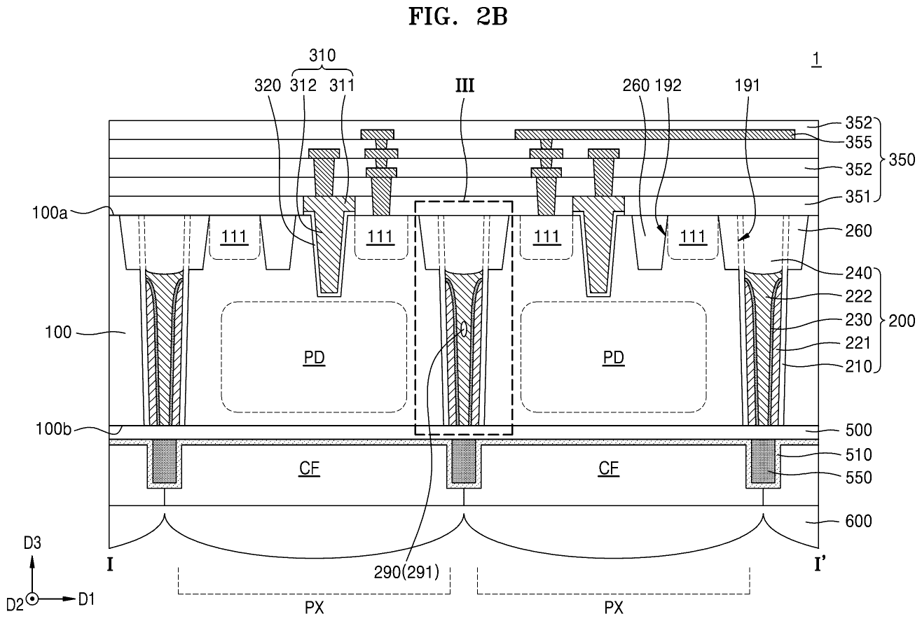

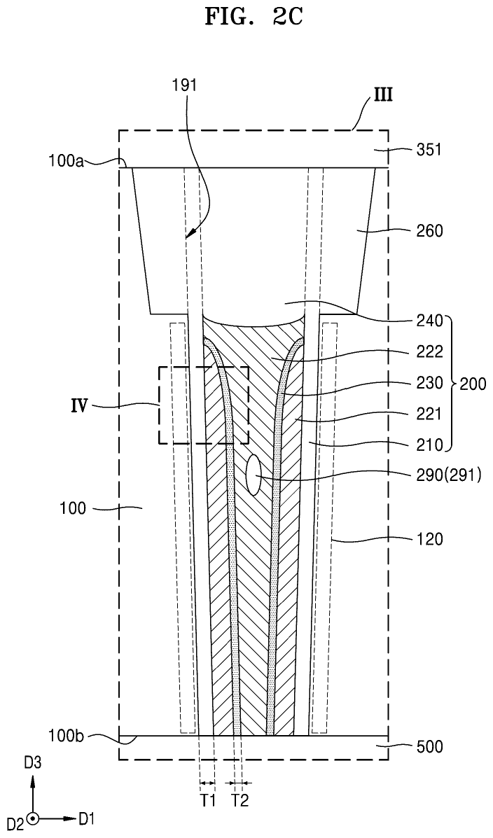

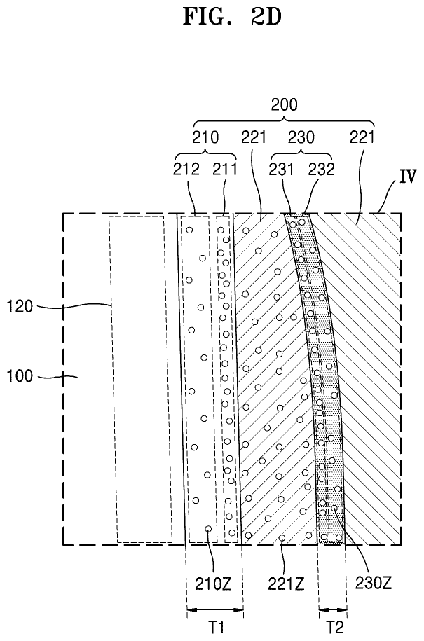

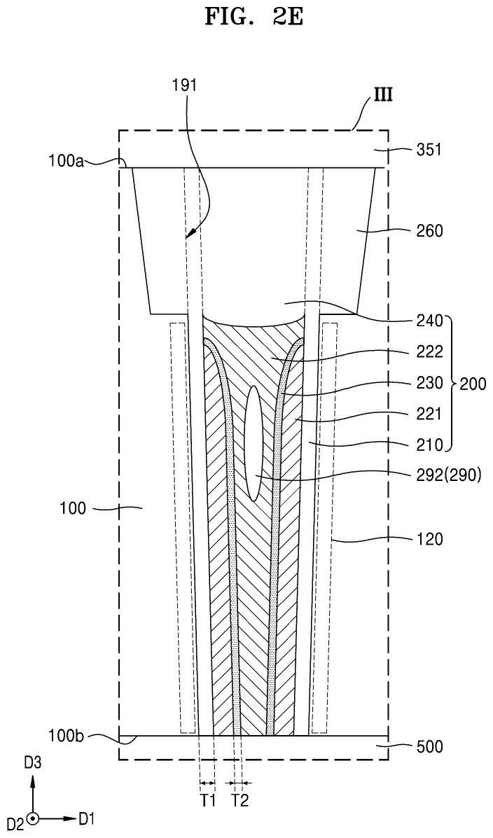

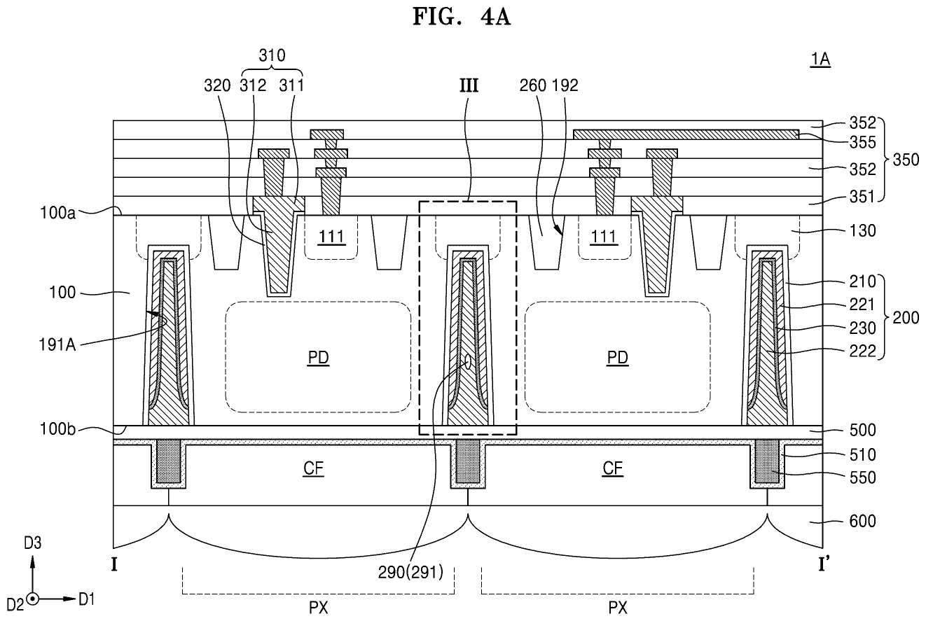

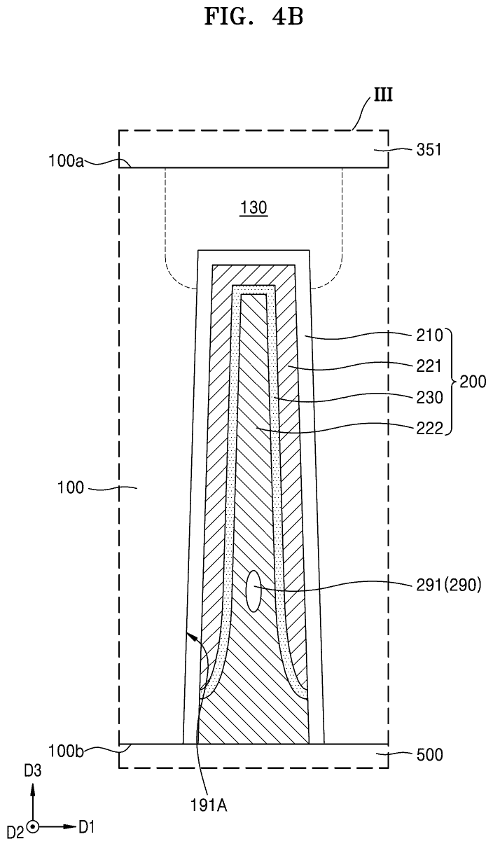

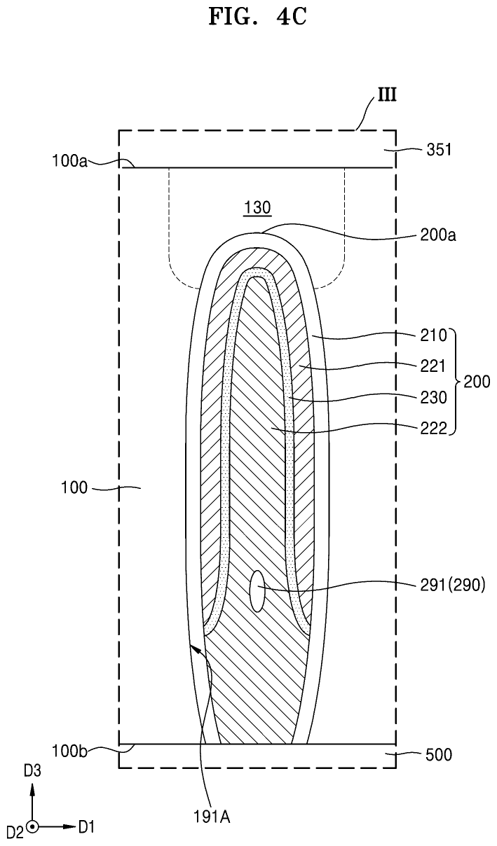

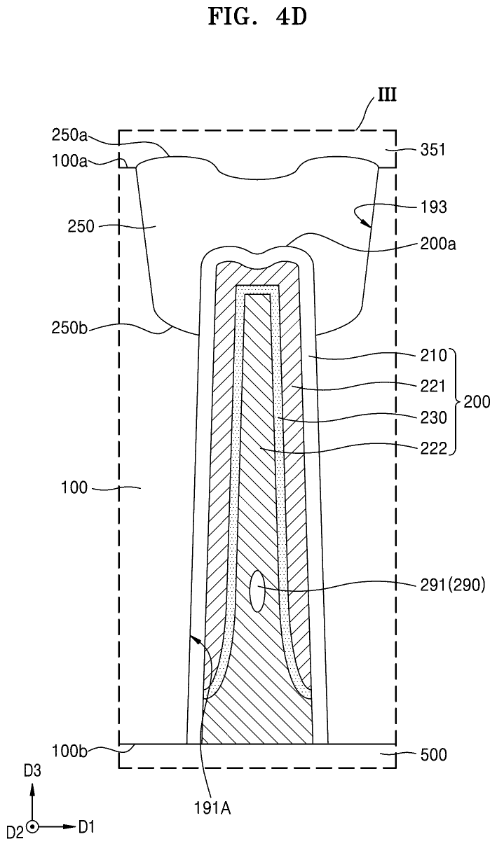

A wiring line may be electrically connected to at least one of the transfer gate TG, the source follower gate SG, the reset gate RG, and the selection gate AG. The wiring line may be configured to apply the power voltage V_{DD} to the drain of the reset transistor Rx or the drain of the source follower transistor Sx. The wiring line may include a column line connected to the selection transistor Ax. The wiring line may include first conductive structures 355 that will be described later with reference to FIGS. 2B and 4A.

Although FIG. 1 illustrates a pixel including one photoelectric conversion region PD and four transistors Tx Rx, Ax, and Sx, implementations are not limited thereto. For example, a plurality of pixels may be provided, and the reset transistor Rx, the source follower transistor Sx, or the selection transistor Ax may be shared by neighboring pixels. Accordingly, an integration degree of the image sensor may be improved.

FIG. 2A is a diagram of an example of a pixel array region of an image sensor. FIG. 2B is a cross-sectional view taken along a line I-I′ of FIG. 2A. FIG. 2C is an enlarged view of a region III of FIG. 2B. FIG. 2D is an enlarged view of a region IV of FIG. 2C. FIG. 2E is an enlarged cross-sectional view showing an example of a deep isolation pattern in a cross section taken along a line II-II′ of FIG. 2A.

Referring to FIGS. 2A to 2E, an image sensor 1 includes a substrate 100, a deep isolation pattern 200, a device isolation pattern 260, a gate pattern 310, a wiring layer 350, color filters CF, and microlens patterns 600.

The plan view of FIG. 2A depicts the substrate 100 including a pixel array region and an edge region. In the plan view of FIG. 2A, the pixel array region is located in a center portion of the substrate 100. The pixel array region includes a plurality of pixel regions PX. The pixels described with reference to FIG. 1 may be formed in each of the pixel regions PX of the substrate 100. For example, components of pixels may be provided on each of the pixel regions PX. The pixel regions PX may output a photoelectric signal from incident light. The pixel regions PX may define rows and columns in terms of a plan view and may be arranged two-dimensionally. The rows may be parallel to a first direction D1. The columns may be parallel to a second direction D2.

The substrate 100 may have a first surface 100a and a second surface 100b facing each other as shown in FIG. 2B. The first surface 100a of the substrate 100 may be a front surface, and the second surface 100b may be a back surface. Light may be incident on the second surface 100b of the substrate 100. The first direction D1 may be parallel to the first surface 100a of the substrate 100. The second direction D2 may be parallel to the first surface 100a of the substrate 100 and may be different from the first direction D1. For example, the second direction D2 may be substantially perpendicular to the first direction D1. A third direction D3 may intersect with the first surface 100a of the substrate 100. The third direction D3 may be a vertical direction. A fourth direction D4 may be substantially parallel to the first surface 100a of the substrate 100 and may intersect with the first direction D1 and the second direction D2. The fourth direction D4 may be a diagonal direction but is not limited thereto.

The substrate 100 may be a semiconductor substrate 100 or a silicon on insulator (SOI) substrate. The semiconductor substrate 100 may include, for example, a silicon substrate, a germanium substrate, or a silicon-germanium substrate. The substrate 100 may include a crystalline semiconductor material. The substrate 100 may include first conductivity type impurities and have a first conductivity type. The first conductivity type impurities may include group 3 elements. For example, the first conductivity type impurities may include p-type impurities such as aluminum (Al), boron (B), phosphorus (P), indium (In), and/or gallium (Ga). The substrate 100 may have a first trench 191 and a second trench 192.

The substrate 100 may include photoelectric conversion regions PD. The photoelectric conversion regions PD may be respectively provided in the pixel regions PX within the substrate 100. Each of the photoelectric conversion regions PD may perform the same function and role as the photoelectric conversion region PD of FIG. 1. The photoelectric conversion regions PD may be regions in the substrate 100, which are doped with second conductive type impurities. The second conductive type impurities may have a conductivity type opposite to that of the first conductivity type impurities. The second conductivity type impurities may include group 5 elements. The second conductive type impurities may include, for example, n-type impurities such as phosphorus, arsenic, bismuth, and/or antimony. The photoelectric conversion regions PD may be located deep in the first surface 100a of the substrate 100.

The deep isolation pattern 200 is provided within the substrate 100 and may define the pixel regions PX. For example, the deep isolation pattern 200 may be provided between the photoelectric conversion regions PD. The deep isolation pattern 200 may be provided in the first trench 191, and the first trench 191 may be formed to pass through the first surface 100a of the substrate 100. For example, the first trench 191 may be recessed from the first surface 100a of the substrate 100. The deep isolation pattern 200 may be a deep trench isolation pattern. The deep isolation pattern 200 may be formed to pass through the first surface 100a of the substrate 100. The deep isolation pattern 200 may be formed to pass further through the second surface 100b of the substrate 100. For example, the deep isolation pattern 200 may be in contact with the first surface 100a and the second surface 100b of the substrate 100. A width of an upper surface of the deep isolation pattern 200 may be larger than a width of a lower surface of the deep isolation pattern 200 but is not limited thereto.

The deep isolation pattern 200 may include a liner film 210, a first pattern 221, a second pattern 222, and an isolation film 230. The liner film 210 may be provided along a sidewall of the first trench 191. The liner film 210 may be formed to pass through the first surface 100a and the second surface 100b of the substrate 100. The liner film 210 may include an oxide film. For example, the liner film 210 may include a silicon-based insulating material (e.g., silicon nitride, silicon oxide, and/or silicon oxynitride) and/or a high dielectric material (e.g., hafnium oxide, tantalum silicate (TaSiOx), and/or aluminum oxide). The liner film 210 may be an insulating film. The liner film 210 may have a lower refractive index than the substrate 100. A thickness T1 (in FIGS. 2C and 2D) of the liner film 210 may be about 150 Å to about 400 Å. The thickness T1 of the liner film 210 may be a thickness in a direction at a point between the first surface 100a of the substrate 100 and a second surface 100b of the substrate 100. The direction may be parallel to the first surface 100a of the substrate 100. The liner film 210 may be a single layer or a multilayer.

The first pattern 221 may be provided on inner sidewalls of the liner film 210 to cover the inner sidewalls of the liner film 210. The first pattern 221 may be a first semiconductor pattern, but is not limited thereto. The first pattern 221 may be spaced apart from the substrate 100 by the liner film 210. Accordingly, when the image sensor 1 operates, the first pattern 221 may be electrically separated from the substrate 100. The inner sidewalls of the liner film 210 may face each other. The first pattern 221 may be formed to pass through the second surface 100b of the substrate 100 but may be spaced apart from the first surface 100a of the substrate 100. The height of the first pattern 221 may be less than the height of the liner film 210. Accordingly, the first pattern 221 may not extend to upper portions of the inner sidewalls of the liner film 210 and may expose the upper portions of the inner sidewalls of the liner film 210. The first pattern 221 may be spaced apart from the upper portions of the inner sidewall of the liner film 210.

For example, the first pattern 221 may be one of the first patterns 221 that are laterally spaced apart from each other. The first patterns 221 may include a crystalline semiconductor material, for example, polysilicon. Hereinafter, for simplicity, a single first pattern 221 will be described.

The second pattern 222 may be provided on the first pattern 221. The second pattern 222 may be provided between the inner sidewalls of the first pattern 221 and may fill a space between the inner sidewalls of the first pattern 221. The second pattern 222 may be a second semiconductor pattern, but is not limited thereto. The second pattern 222 may include a crystalline semiconductor material, for example, polysilicon. However, the second pattern 222 may include, for example, undoped polysilicon. Alternatively, the second pattern 222 may include doped polysilicon.

The isolation film 230 may be provided between the first pattern 221 and the second pattern 222. The first pattern 221 may conformally cover the inner sidewalls of the first pattern 221. The isolation film 230 may continuously extend on the inner sidewalls of the first pattern 221 to prevent outer sidewalls of the first pattern 221 from being exposed. The second pattern 222 may be spaced apart from the first pattern 221 by the isolation film 230. For example, the second pattern 222 may not be in direct contact with the first pattern 221, e.g., the first and second patterns 221 and 222 are separated by the isolation film 230. For example, the first pattern 221 may be spaced apart from the substrate 100 by the liner film 210 in the first direction D1. An uppermost surface of the isolation film 230 may be provided at a lower level than an upper surface of the second pattern 222. In this specification, a level of a certain component may mean a vertical level measured in a vertical direction. A level difference, e.g., a distance, between the two components may be measured in a direction parallel to the third direction D3.

The isolation film 230 may be provided between the first pattern 221 and the second pattern 222, and thus a grain size of the second pattern 222 may be different from that of the first pattern 221. The grain size of the second pattern 222 may be larger than that of the first pattern 221. A crystal orientation of the second pattern 222 may be different from that of the first pattern 221, in a cross section view. When the first and second patterns 221 and 222 are in direct contact with each other, the grain size of the second pattern 222 may be the same or similar to that of the first pattern 221. When the first and second patterns 221 and 222 are in direct contact with each other, a crystal orientation of the second pattern 222 may be the same as that of the first pattern 221. The grain size of a certain component be an average diameter of grains of the certain component in a reference crystal orientation, in a cross section view. The reference crystal orientation may be selected from a <110> direction, a <111> direction, and a <110> direction. The first pattern may include a plurality of grains. The grain size of the first pattern 221 may be an average value of diameters of the plurality of grains of the first pattern 221. The diameters of the plurality of grains of the first pattern 221 may be measured in the reference crystal orientation of each of the grains of the first pattern 221. For example, when the diameter of one of the grains of the first pattern 221 is measured in the <110> direction, the diameters of others of the grains of the pattern 221 may also be measured in the <110> direction. The second pattern 222 may include a plurality of grains. The grain size of the second pattern 222 may be an average value of diameters of the plurality of grains of the second pattern 222. The diameters of the plurality of grains of the second pattern 222 may be measured in the reference crystal orientation of each of the grains of the second pattern 222. For example. When the diameter of one of the grains of the second pattern 222 is measured in the <110> direction, the diameter of others of the grains of the second pattern 222 can also be measured in the <110> direction. The size of the grain of the first pattern 221 and the size of the second pattern 222 can be measured in the same reference crystal orientation.

The isolation film 230 may include a material different from the first pattern 221 and the second pattern 222. Accordingly, the isolation film 230 may have characteristics different from the first pattern 221 and the second pattern 222. For example, the isolation film 230 may include an oxide film. The isolation film 230 may include silicon oxide. Alternatively, the isolation film 230 may include silicon oxynitride. For example, the isolation film 230 may include the same material as the liner film 210. In this case, an interface between the isolation film 230 and the liner film 210 may not be distinct. As another example, the isolation film 230 may include a material different from the liner film 210. A thickness T2 of the isolation film 230 may be less than a thickness Tl of the liner film 210. For example, the thickness T2 of the isolation film 230 may be about 6 Å to about 15 Å. The thickness T2 of the isolation film 230 may be a thickness in a direction at a point between the first surface 100a of the substrate 100 and a second surface 100b of the substrate 100. The direction may be parallel to the first surface 100a of the substrate 100. In this specification, when referring to ranges, the term “about” refers to a value within ±10%.

As shown in FIG. 2D, the first pattern 221 may further include a first dopant 221Z. The first dopant 221Z may include the first conductivity type impurities. For example, the first dopant 221Z may include boron (B). As another example, the first dopant 221Z may include phosphorus (P). A concentration of the first dopant 221Z of the first pattern 221 may be 5.0×10¹⁹ atom/cm³ to 5.0×10²² atom/cm³.

The isolation film 230 may further include a first additional element 230Z. The first additional element 230Z may be the same element as the first dopant 221Z. For example, the first additional element 230Z may include boron (B). As another example, the first additional element 230Z may include phosphorus (P). The isolation film 230 may include a first portion 231 and a second portion 232. The first portion 231 of the isolation film 230 may be provided between the second portion 232 and the first pattern 221. For example, the first portion 231 of the isolation film 230 may contact inner sidewalls of the first pattern 221. The thickness of the first portion 231 of the isolation film 230 may be less than the thickness of the second portion 232. Each of the first portion 231 and the second portion 232 of the isolation film 230 may include the first additional element 230Z. The first dopant 221Z of the first pattern 221 may diffuse into the isolation film 230 to form the first additional element 230Z, but is not limited thereto. For example, the first dopant 221Z of the first pattern 221 may diffuse into the first portion 231 of the isolation film 230 to form the first additional element 230Z. A concentration of the first additional element 230z in the first portion 231 of the isolation film 230 may be greater than a concentration of the first additional element 230z in the second portion 232 of the isolation film 230.

The liner film 210 may further include a second additional element 210Z. The second additional element 210Z may include the same element as the first dopant 221Z and the first additional element 230Z. For example, the second additional element 210Z may include boron (B). As another example, the second additional element 210Z may include phosphorus (P). The liner film 210 may include a first lateral portion 211 and a second lateral portion 212. The first lateral portion 211 of the liner film 210 may be provided between the second lateral portion 212 and the first pattern 221. For example, the first lateral portion 211 of the liner film 210 may be in contact with the outer sidewall of the first pattern 221. The thickness of the first lateral portion 211 of the liner film 210 may be less than the thickness of the second lateral portion 212. Each of the first lateral portion 211 and the second lateral portion 212 of the liner film 210 may include the second additional element 210Z. A concentration of the second additional element 210Z in the first lateral portion 211 of the liner film 210 may be greater than a concentration of the second additional element 210Z in the second lateral portion 212 of the liner film 210. The first dopant 221Z of the first pattern 221 may diffuse into the liner film 210 to form the second additional element 210Z, but is not limited thereto.

The deep isolation pattern 200 may have a void 290 therein. The void 290 may be provided in the second pattern 222. The deep isolation pattern 200 may have a first region R1, a second region R2, and a cross region CR in terms of a plan view as shown in FIG. 2A. The first region R1 of the deep isolation pattern 200 may extend in the first direction D1. The second region R2 of the deep isolation pattern 200 may extend in the second direction D2. The cross region CR of the deep isolation pattern 200 may be a region in which the first region R1 and the second region R2 intersect with each other.

The void 290 may be one of a plurality of voids 290. For example, the void 290 may include a first void 291 and a second void 292. The second void 292 may be provided in the cross region CR of the deep isolation pattern 200. The first void 291 may be provided in the first region R1 or the second region R2 of the deep isolation pattern 200. As shown in FIGS. 2A, 2C, and 2E, the size of the second void 292 may be larger than the size of the first void 291. The cross-sectional area of the second void 292 may be larger than the cross-sectional area of the first void 291. The cross-sectional area of the first void 291 and the cross-sectional area of the second void 292 may be measured at a point between the first surface 100a of the substrate 100 and the second surface 100b of the substrate 100. Each of the first void 291 and the second void 292 may be spaced apart from the first pattern 221.

When the void 290 is larger than a predetermined size, a defect in the image sensor 1 may occur. The defect may include white spots or dark characteristics. In some implementations, the isolation film 230 may be provided, and thus the void 290 may be less than a predetermined size. Accordingly, defects in the image sensor 1 may be prevented. As a result, the image sensor 1 may have improved image characteristics.

When the void 290 is larger than a predetermined size, damage to an image sensor chip may occur during a packaging process of the image sensor chip. The image sensor chip may include the image sensor 1. For example, damage to an image sensor chip may include formation of cracks in the image sensor chip. In some implementations, even if the void 290 is formed in the deep isolation pattern 200, the image sensor chip may have improved intensity because the void 290 is less than a predetermined size.

The deep isolation pattern 200 may further include a capping pattern 240. The capping pattern 240 may be provided on the second pattern 222. The capping pattern 240 may fill an upper portion of the first trench 191. The liner film 210 may further extend between the substrate 100 and the capping pattern 240. For example, the liner film 210 may be located between the device isolation pattern 260 and the capping pattern 240. For example, the capping pattern 240 may include a silicon-containing insulating material (e.g., silicon oxide, tetraethyl orthosilicate (TEOS), and/or silicon oxynitride).

The image sensor 1 may further include a doped region 120 as shown in FIG. 2C. The doped region 120 may be provided adjacent to the deep isolation pattern 200 within the substrate 100. For example, the doped region 120 may be provided along the outer wall of the deep isolation pattern 200. The first trench 191 may expose the doped region 120. The doped region 120 may be a region doped with first conductivity type impurities. The doped region 120 may prevent dark current in the image sensor 1 from being generated. Hereinafter, for simplification, the doped region 120 is omitted in the drawings except for FIGS. 2B to 2D but the inventive concept is not limited thereto.

As shown in FIG. 2B, the substrate 100 may have impurity regions 111. The impurity regions 111 may be respectively located in the pixel regions PX within the substrate 100. The impurity regions 111 may be located adjacent to the first surface 100a of the substrate 100. The impurity regions 111 may be spaced apart from the photoelectric conversion regions PD. The impurity regions 111 may be regions doped with second conductive type impurities (e.g., n-type impurities). Accordingly, the impurity regions 111 may have a second conductivity type. The impurity regions 111 may be active regions or ground regions. In this case, the active regions are a region for an operation of a transistor and may include the floating diffusion region FD and the source/drain regions of the transistor described with reference to FIG. 1. The transistor may include the transfer transistor Tx, the source follower transistor Sx, the reset transistor Rx, or the selection transistor Ax described with reference to FIG. 1.

The device isolation pattern 260 may be provided within the substrate 100 adjacent to the first surface 100a of the substrate 100. The device isolation pattern 260 may be formed to pass through the first surface 100a of the substrate 100. The device isolation pattern 260 may define active regions or ground regions. In detail, in each pixel region PX, the device isolation pattern 260 may define the impurity regions 111, and the impurity regions 111 may be separated from each other by the device isolation pattern 260. For example, the device isolation pattern 260 may be located on one side of one of the impurity regions 111 within the substrate 100. A lower portion of the device isolation pattern 260 may be provided within the substrate 100. For example, the device isolation pattern 260 may be provided in the second trench 192. The second trench 192 may be recessed from the first surface 100a of the substrate 100. The device isolation pattern 260 may be a shallow trench isolation (STI) pattern. For example, the height of the device isolation pattern 260 may be less than the height of the deep isolation pattern 200. At least a portion of the device isolation pattern 260 may be located on the upper portion of the outer sidewall of the deep isolation pattern 200 and may be connected to the upper portion of the outer sidewall of the deep isolation pattern 200. For example, at least a portion of the device isolation pattern 260 may be connected to the upper portion of the outer sidewall of the liner film 210. The sidewall of the device isolation pattern 260, a lower surface of the device isolation pattern 260, and the outer sidewall of the deep isolation pattern 200 may have a stepped structure. The device isolation pattern 260 may include, for example, silicon oxide, silicon nitride, and/or silicon oxynitride. When the device isolation pattern 260 includes the same material as the liner film 210, an interface between the device isolation pattern 260 and the liner film 210 that are in contact with each other may not be distinct structures. However, implementations are not limited thereto.

As shown in FIG. 2B, the gate pattern 310 may be provided on the first surface 100a of the substrate 100. The gate pattern 310 may function as a gate electrode of the transfer transistor Tx, the source follower transistor Sx, the reset transistor Rx, or the selection transistor Ax described above with reference to FIG. 1. For example, the gate pattern 310 may include the transfer gate TG, the source follower gate SG, the reset gate RG, or the selection gate AG. For simplicity, although FIG. 2B illustrates that a single gate pattern 310 is located on each pixel region PX, a plurality of gate patterns 310 may be located on each pixel region PX. Hereinafter, for simplicity, a single gate pattern 310 will be described.

The gate pattern 310 may have a buried gate structure. For example, the gate pattern 310 may include a first portion 311 and a second portion 312. The first portion 311 of the gate pattern 310 may be disposed on the first surface 100a of the substrate 100. The second portion 312 of the gate pattern 310 may protrude into the substrate 100. The second portion 312 of the gate pattern 310 may be connected to the first portion 311. In some implementations, the gate pattern 310 may have a planar gate structure. In this case, the gate electrode may not include the second portion 312. The gate pattern 310 may include a metal material, a metal silicide material, polysilicon, and combinations thereof. In this case, polysilicon may include doped polysilicon.

The image sensor 1 may further include a gate insulating pattern 320. The gate insulating pattern 320 may be located between the gate pattern 310 and the substrate 100. The gate insulating pattern 320 may include, for example, a silicon-based insulating material (e.g., silicon oxide, silicon nitride, and/or silicon oxynitride) and/or a high dielectric material (e.g., hafnium oxide and/or aluminum oxide).

The wiring layer 350 may be provided on the first surface 100a of the substrate 100. The wiring layer 350 may include a first insulating layer 351, second insulating layers 352, and the first conductive structures 355. The first insulating layer 351 may be provided on the first surface 100a of the substrate 100 and the sidewall of the gate pattern 310. The second insulating layers 352 may be stacked on the first insulating layer 351. The first and second insulating layers 351 and 352 may include, for example, a silicon-based insulating material such as silicon oxide, silicon nitride, and/or silicon oxynitride.

The first conductive structures 355 may be provided in the insulating layers 351 and 352. Each of the first conductive structures 355 may include a contact plug portion, a wiring portion, and a via portion. The contact plug portion may be provided in at least one of the first insulating layer 351 and the lowermost second insulating layer 352. The contact plug portion may be electrically connected to one of the impurity regions 111 and the gate pattern 310. The wiring portion of each of the conductive structures 355 may be located between two adjacent insulating layers 351 and 352. The wiring portion may be connected to the contact plug portion. The via portion of each of the conductive structures 355 may be formed to pass through at least one of the second insulating layers 352 and may be connected to the wiring portion. The conductive structures 355 may receive photoelectric signals that is output from the photoelectric conversion regions PD.

The image sensor 1 may further include a back surface insulating layer 500. The back surface insulating layer 500 may be disposed on the second surface 100b of the substrate 100 and may cover the second surface 100b of the substrate 100 and a lower surface of the deep isolation pattern 200. Although not shown, the back surface insulating layer 500 may include multiple layers. Two adjacent layers of the back surface insulating layer 500 may include different materials. For example, the back surface insulating layer 500 may include a metal oxide (e.g., aluminum oxide or hafnium oxide) or a silicon-based insulating material (e.g., silicon oxide or silicon nitride). Layers of the back surface insulating layer 500 may perform different functions. For example, the back surface insulating layer 500 may include at least one of a bottom antireflective coating (BARC) layer, a fixed charge layer, an adhesive layer, and a protective layer.

The color filters CF may be provided at positions corresponding to the pixel regions PX on the lower surface of the back surface insulating layer 500. For example, the color filters CF may be located on of the pixel regions PX, respectively. In some implementations, the color filters CF may be embedded in the back surface insulating layer 500. The color filters CF may include a red filter, a blue filter, and a green filter. At least one of the color filters CF may further include a white filter but the inventive concept not limited thereto.

The image sensor 1 may further include a grid pattern 550. The grid pattern 550 may be provided on the lower surface of the back surface insulating layer 500 and may be located between the color filters CF. The grid pattern 550 may include a metal such as tungsten, a metal nitride such as titanium nitride, or a silicon-containing material such as silicon oxide.

The microlens patterns 600 may be disposed on the second surface 100b of the substrate 100. For example, the microlens patterns 600 may be disposed on the lower surfaces of the color filters CF, respectively. The microlens patterns 600 may be provided at positions corresponding to the photoelectric conversion regions PD. For example, the microlens patterns 600 may vertically overlap the photoelectric conversion regions PD, respectively. Each of the microlens patterns 600 may protrude away from the second surface 100b of the substrate 100. The microlens patterns 600 may be connected to each other. The microlens patterns 600 are transparent and may transmit light. The microlens patterns 600 may include an organic material such as a polymer. For example, the microlens patterns 600 may include a photoresist material or a thermosetting resin.

The image sensor 1 may further include a protective film 510. The protective film 510 may be located between the back surface insulating layer 500 and the color filters CF and between the grid pattern 550 and the color filters CF. The protective film 510 may include an insulating material such as a high dielectric material. For example, the protective film 510 may include an aluminum oxide or a hafnium oxide.

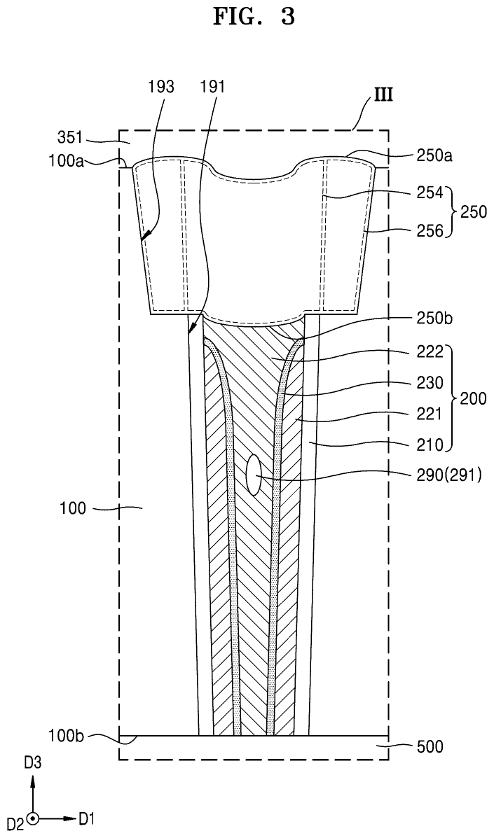

FIG. 3 is a diagram of an example of a deep isolation pattern and corresponds to an enlarged cross-section of region III of FIG. 2B.

Referring to FIG. 3, the deep isolation pattern 200 further includes a shallow insulation pattern 250 in addition to the liner film 210, the first pattern 221, the second pattern 222, and the isolation film 230. However, in some implementations, the deep isolation pattern 200 does not include the capping pattern 240.

The shallow insulation pattern 250 may be provided within the substrate 100. For example, the shallow insulation pattern 250 may be provided in a third trench 193 of the substrate 100. The third trench and the shallow insulation pattern 250 may be formed to pass through the first surface 100a of the substrate 100. The shallow insulation pattern 250 may be located between the deep isolation pattern 200 and the first insulating layer 351 and may extend horizontally along the lower surface of the first insulating layer 351. The width of the shallow insulation pattern 250 may be greater than the width of the deep isolation pattern 200. For example, the width of the lower portion of the shallow insulation pattern 250 may be greater than the width of the upper portion of the deep isolation pattern 200. A lower surface 250b of the shallow insulation pattern 250 may be in physical contact with the deep isolation pattern 200 and the substrate 100.

For example, the lower surface 250b of the shallow insulation pattern 250 may not be flat. The lower surface 250b of the shallow insulation pattern 250 may include at least one of a protrusion and a recess, but is not limited thereto. For example, the lower surface 250b of the shallow insulation pattern 250 may be located at substantially the same level as the lower surface of the device isolation pattern 260 of FIG. 2B, but is not limited thereto. For example, the shallow insulation pattern 250 may include the same material as the device isolation pattern 260 of FIG. 2B, but is not limited thereto.

For example, an upper surface 250a of the shallow insulation pattern 250 may not be flat. For example, the upper surface 250a of the shallow insulation pattern 250 may include at least one of a protrusion and a recess, but is not limited thereto.

The shallow insulation pattern 250 may include a capping portion 254 and a device isolation portion 256. The capping portion 254 may be located between the deep isolation pattern 200 and the first insulating layer 351. For example, the capping portion 254 may be located between the second pattern 222 and the first insulating layer 351. The device isolation portion 256 may be disposed on the sidewalls of the capping portion 254. The shallow insulation pattern 250 may include a silicon-based insulating material. The shallow insulation pattern 250 may include, for example, silicon oxide, silicon nitride, and/or silicon oxynitride.

FIG. 4A is a cross-sectional view of an example of an image sensor and corresponds to a cross-section taken along a line I-I′ of FIG. 2A. FIG. 4B is an enlarged view of a region III of FIG. 4A. Hereinafter, a repeated explanation of the above description will not be given.

Referring to FIGS. 4A to 4B, an image sensor 1A includes the substrate 100, the deep isolation pattern 200, the device isolation pattern 260, the gate pattern 310, the wiring layer 350, the color filters CF, and the microlens patterns 600. The image sensor 1A may further include the back surface insulating layer 500, the protective film 510, and the grid pattern 550.

The deep isolation pattern 200 may be provided within the substrate 100 and may define the pixel regions PX. The deep isolation pattern 200 may be provided in a back surface trench 191A. The back surface trench 191A may be formed to pass through the second surface 100b of the substrate 100. A bottom surface of the back surface trench 191A may be provided within the substrate 100. An upper surface of the deep isolation pattern 200 may correspond to the bottom surface of the back surface trench 191A. The upper surface of the deep isolation pattern 200 may be spaced apart from the first surface 100a of the substrate 100 and may be located at a level lower than the first surface 100a. Unlike shown, the back surface trench 191A and the deep isolation pattern 200 may be formed to pass further through first surface 100a of the substrate 100. A width of an upper surface of the deep isolation pattern 200 may be larger than a width of a lower surface of the deep isolation pattern 200.

The substrate 100 may further have a pixel isolation region 130. The pixel isolation region 130 may define pixel regions PX together with the deep isolation pattern 200. The pixel isolation region 130 may be provided within the substrate 100. The pixel isolation region 130 may be provided between the upper surface of the deep isolation pattern 200 and the first surface 100a of the substrate 100. For example, the device isolation pattern 260 may be further located between the pixel isolation region 130 and the impurity regions 111. The pixel isolation region 130 may include group 3 elements. For example, the pixel isolation region 130 may be a region doped with first conductivity type (e.g., p type) impurities.

The upper surface of the deep isolation pattern 200 may be provided within the pixel isolation region 130. The upper portion of the deep isolation pattern 200 may be surrounded by the pixel isolation region 130.

The deep isolation pattern 200 may include the liner film 210, the first pattern 221, the second pattern 222, and the isolation film 230. The liner film 210, the first pattern 221, the second pattern 222, and isolation film 230 may be the same or similar to those described in the examples of FIGS. 2A to 2E. However, the liner film 210 may cover the inner sidewalls and bottom surface of the back surface trench 191A. The pixel isolation region 130 may be in contact with the upper surface of the liner film 210. The first pattern 221 may cover the inner sidewalls of the liner film 210. The first pattern 221 may extend onto the bottom surface of the back surface trench 191A and further cover the liner film 210. The height of the first pattern 221 may be less than the height of the liner film 210. The first pattern 221 may expose portions of the inner sidewalls of the liner film 210. For example, the first pattern 221 may expose lower portions of the inner sidewalls of the liner film 210. The second pattern 222 may be provided between the inner sidewalls of the first pattern 221 and may fill a space between the inner sidewalls of the first pattern 221. The second pattern 222 may cover lower portions of the inner sidewall of the liner film 210. The isolation film 230 may be provided between the first pattern 221 and the second pattern 222. The isolation film 230 may conformally cover the inner sidewalls of the first pattern 221. The deep isolation pattern 200 may not include the capping pattern 240 of FIG. 2B. As shown, the deep isolation pattern 200 may further include the capping pattern 240 of FIG. 2B, and the capping pattern 240 may be located between the second pattern 222 and the back surface insulating layer 500 in the back surface trench 191A.

FIG. 4C is a diagram of an example of a deep isolation pattern and corresponds to an enlarged cross-section of a region III of FIG. 4A. Hereinafter, a repeated explanation of the above description will not be given.

Referring to FIG. 4C, the deep isolation pattern 200 may be formed to pass through the second surface 100b of the substrate 100. For example, the deep isolation pattern 200 may be provided in the back surface trench 191A. The deep isolation pattern 200 may include the liner film 210, the first pattern 221, the second pattern 222, and the isolation film 230.

An upper surface 200a of the deep isolation pattern 200 may be rounded. For example, a center region of the upper surface 200a of the deep isolation pattern 200 may be provided at a higher level than edge regions of the upper surface 200a of the deep isolation pattern 200. The upper surface 200a of the deep isolation pattern 200 may be provided within the pixel isolation region 130 and may be surrounded by the pixel isolation region 130.

The deep isolation pattern 200 may have a baseball bat-like shape. For example, the upper portion of the deep isolation pattern 200 may have a width less than a middle portion. The lower portion of the deep isolation pattern 200 may have a width less than the middle portion. A cross-sectional shape of the deep isolation pattern 200 may be modified in various ways.

FIG. 4D is a diagram of an example of a deep isolation pattern and corresponds to an enlarged cross-section of a region III of FIG. 4A.

Referring to FIG. 4D and FIG. 4A, the image sensor 1A may further include the shallow insulation pattern 250. The shallow insulation pattern 250 may define pixel regions PX together with the deep isolation pattern 200. The shallow insulation pattern 250 may be the same or similar to the shallow insulation pattern 250 of FIG. 3. For example, the shallow insulation pattern 250 may be provided in a third trench 193 of the substrate 100. The shallow insulation pattern 250 may be provided between the upper surface 200a of the deep isolation pattern 200 and the first surface 100a of the substrate 100. The upper surface 250a of the shallow insulation pattern 250 may not be flat but is not limited thereto. The lower surface 250b of the shallow insulation pattern 250 may not be flat. For example, the lower surface 250b of the shallow insulation pattern 250 may have a downward convex shape. The shallow insulation pattern 250 may include a silicon-based insulating material.

The shallow insulation pattern 250 may be formed through a single process with the device isolation pattern 260 of FIG. 2B but is not limited thereto. For example, the shallow insulation pattern 250 may include the same material as the device isolation pattern 260 of FIG. 4A, but is not limited thereto.

The upper surface 200a of the deep isolation pattern 200 may be provided within the shallow insulation pattern 250. For example, the upper portion of the deep isolation pattern 200 may be surrounded by the shallow insulation pattern 250. The upper surface 200a of the deep isolation pattern 200 may not be flat. For example, the upper surface 200a of the deep isolation pattern 200 may include at least one of a protrusion and a recess.

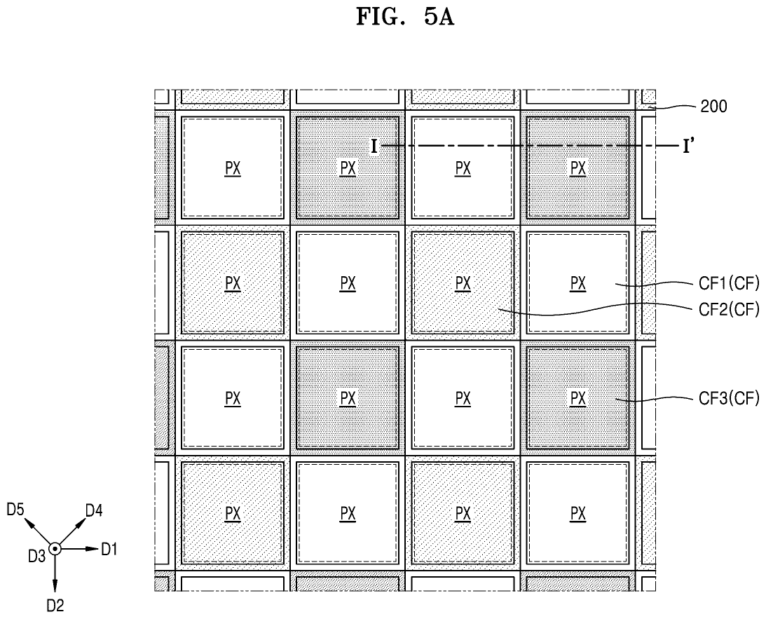

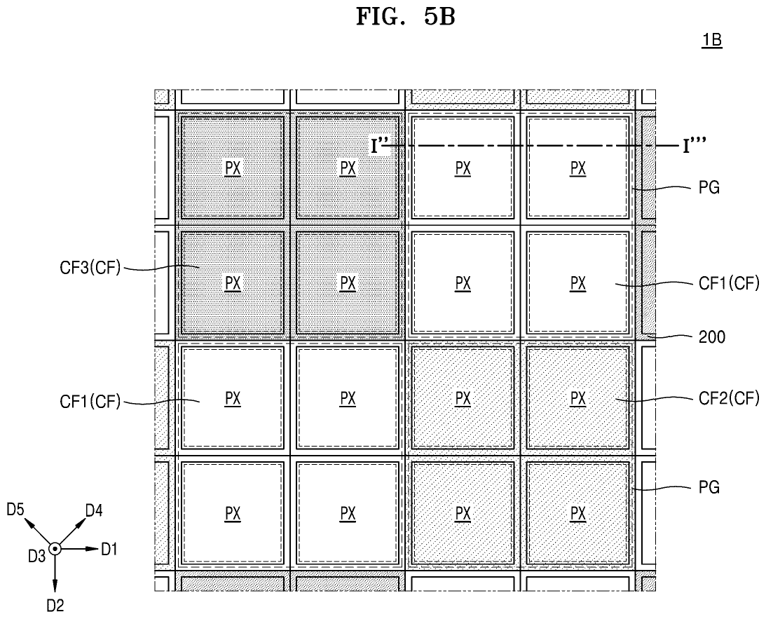

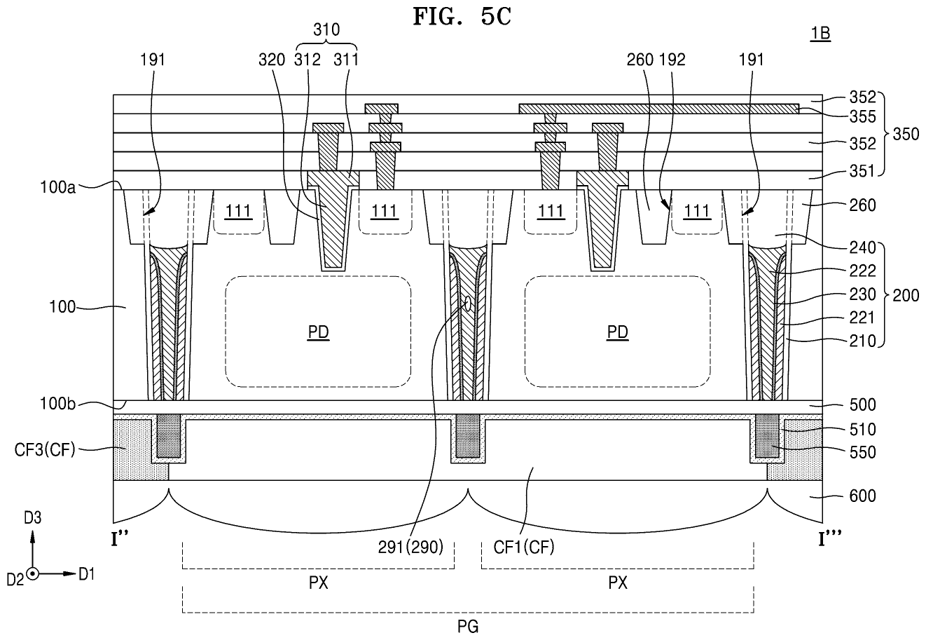

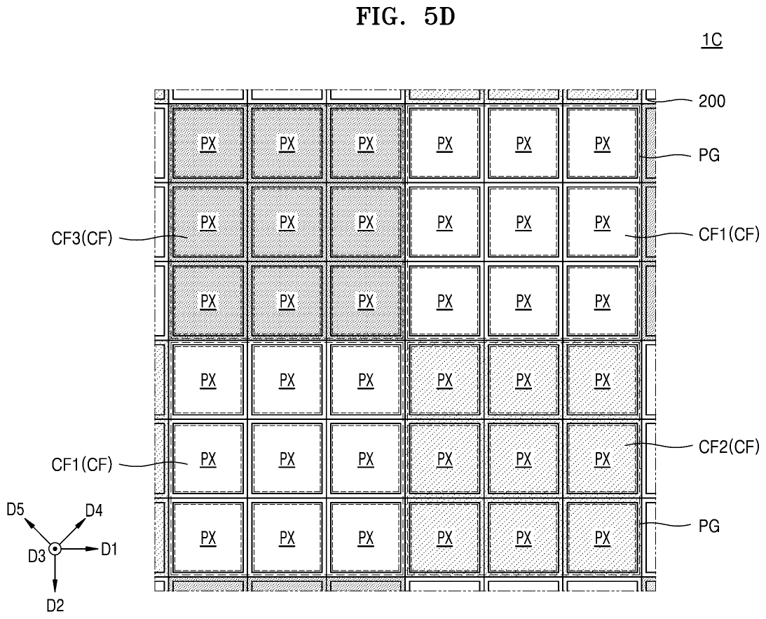

FIG. 5A is a plan view depicting an example of an arrangement of color filters of an image sensor. A cross section taken along a line I-I′ in FIG. 5A corresponds to FIG. 2B. For simplicity, the liner film 210, the first pattern 221, the second pattern 222, and the isolation film 230 are omitted in FIGS. 5A, 5B, and 5D.

Referring to FIG. 5A together with FIG. 2A, the pixel array region of the substrate 100 may include the plurality of pixel regions PX. The deep isolation pattern 200 may be located between the pixel regions PX. The deep isolation pattern 200 may surround each of the pixel regions PX in terms of a plan view.

The color filters CF may be located on of the pixel regions PX, respectively. The color filters CF may be substantially the same as the color filters CF described in the example of FIG. 2B. The color filters CF may include first color filters CF1, second color filters CF2, and third color filters CF3. The first color filters CF1 may be green color filters. The green color filters allow green light to pass through in visible light. When the photoelectric conversion regions PD are provided on the first color filters CF1, the photoelectric conversion regions PD may generate photoelectrons corresponding to green light. The second color filters CF2 may include red color filters, and the third color filters CF3 may include blue color filters.

The color filters CF may be arranged in a Bayer pattern. For example, the number of first color filters CF1 may be greater than the number of second color filters CF2. For example, the number of first color filters CF1 may be equal to or greater than twice the number of the second color filters CF2. The number of first color filters CF1 may be greater than the number of third color filters CF3. For example, the number of first color filters CF1 may be equal to or greater than twice the number of the third color filters CF3. The first color filters CF1 may be arranged in the fourth direction D4. Each of the second color filters CF2 may be located between two adjacent first color filters CF1. Each of the third color filters CF3 may be located between two adjacent first color filters CF1. The third color filters CF3 may be arranged with the second color filters CF2 in a fifth direction D5. The fifth direction D5 may be parallel to the first surface 100a of the substrate 100 and may intersect with the first direction D1, the second direction D2, and the fourth direction D4. For example, the fifth direction D5 may be substantially perpendicular to the fourth direction D4.

FIG. 5B is a plan view depicting an example of an arrangement of color filters of an image sensor. FIG. 5C is a cross-sectional view taken along a line I″-I′″ of FIG. 5B. Hereinafter, for simplicity, a singular first color filter, a singular second color filter, and a singular third color filter will be described.

Referring to FIGS. 5B and 5C, an image sensor 1B may include the substrate 100, the deep isolation pattern 200, the device isolation pattern 260, the gate pattern 310, the wiring layer 350, the color filters CF, and the microlens patterns 600.

The substrate 100 may include pixel groups PG. The pixel groups PG may be two-dimensionally arranged in the first direction D1 and the second direction D2 in terms of a plan view. Each of the pixel groups PG may include the plurality of pixel regions PX. For example, the pixel regions PX of the pixel groups PG may be arranged two-dimensionally, defining two rows and two columns.

The color filters CF may be located in the pixel groups PG on the second surface 100b of the substrate 100, respectively. The color filters CF may be substantially the same as the color filters CF described in the example of FIG. 5A. The color filters CF may include a first color filter CF1, a second color filter CF2, and a third color filter CF3. The first color filter CF1, the second color filter CF2, and the third color filter CF3 may be arranged in a Bayer pattern manner as described in FIG. 5A. However, a single color filter CF may be disposed on one of the pixel groups PG and overlap the plurality of pixel regions PX of one of the pixel groups PG in terms of a plan view. The single color filter CF may be disposed on the photoelectric conversion regions PD of the plurality of pixel regions PX of the pixel group PG. Accordingly, the plurality of pixel regions PX of the pixel group PG may share the single color filter CF. For example, the first color filter CF1 may be disposed on the plurality of pixel regions PX of one pixel group PG. The second color filter CF2 may be disposed on the plurality of pixel regions PX of another pixel group PG. The third color filter CF3 may be disposed on the plurality of pixel regions PX of another pixel group PG. The image sensor 1B may have a tetra-cell structure.

FIG. 5D is a plan view depicting an example of an arrangement of color filters of an image sensor.

Referring to FIG. 5D, the pixel array region of an image sensor 1C may have a nona-cell structure. In this case, each of the pixel groups PG may include nine pixel regions PX. The nine pixel regions PX may be arranged two-dimensionally, defining three rows and three columns. The single color filter CF may be provided to nine pixel regions PX of any one of the pixel groups PG to overlap the nine pixel regions PX. The first color filter CF1, the second color filter CF2, and the third color filter CF3 may be arranged in a Bayer pattern manner.

In this specification, features from different examples may be combined with each other. For example, the embodiments of FIGS. 2A to 2E, the embodiment of FIG. 3, the embodiment of FIGS. 4A and 4B, the embodiment of FIG. 4C, the embodiment of FIG. 4D, the embodiment of FIG. 5A, the embodiments of FIGS. 5B and 5C, and the embodiments of FIG. 5D may be combined with each other in a single device.

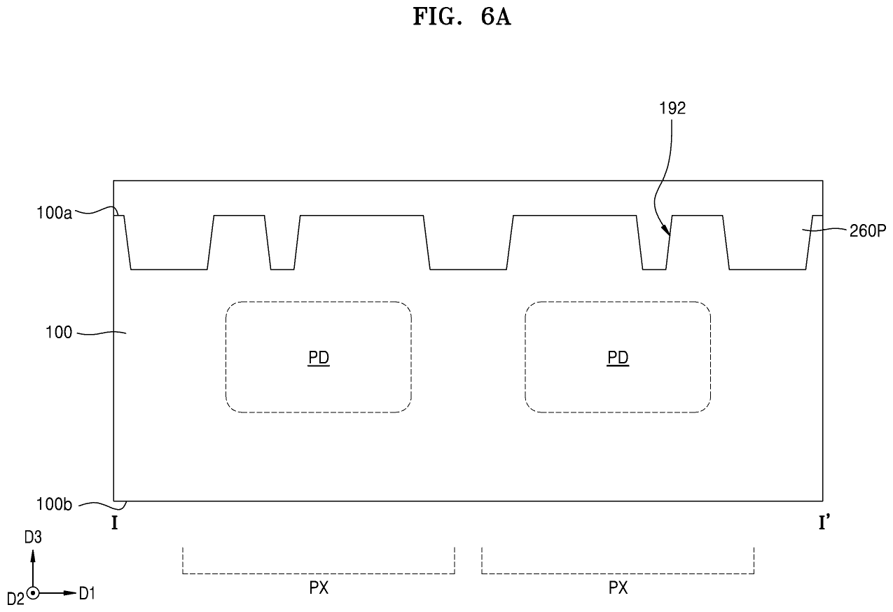

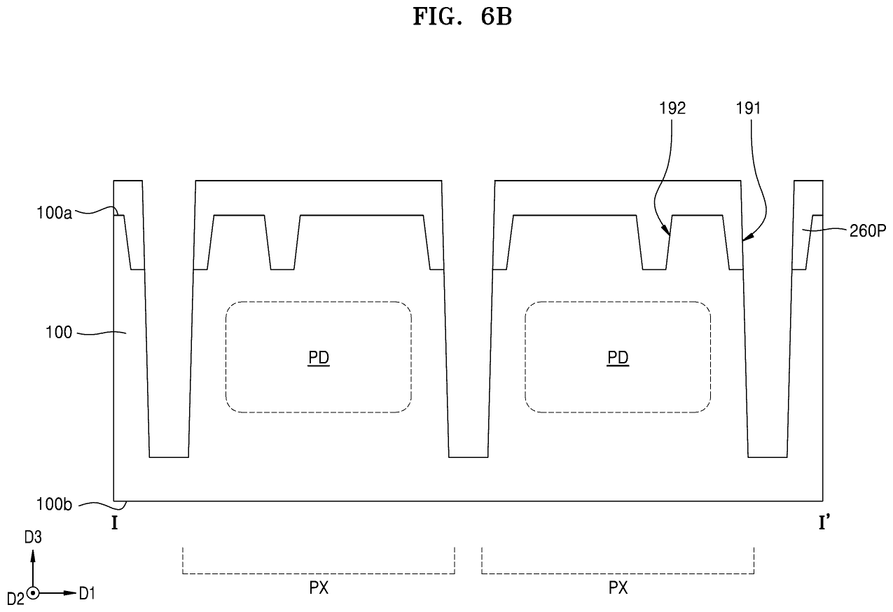

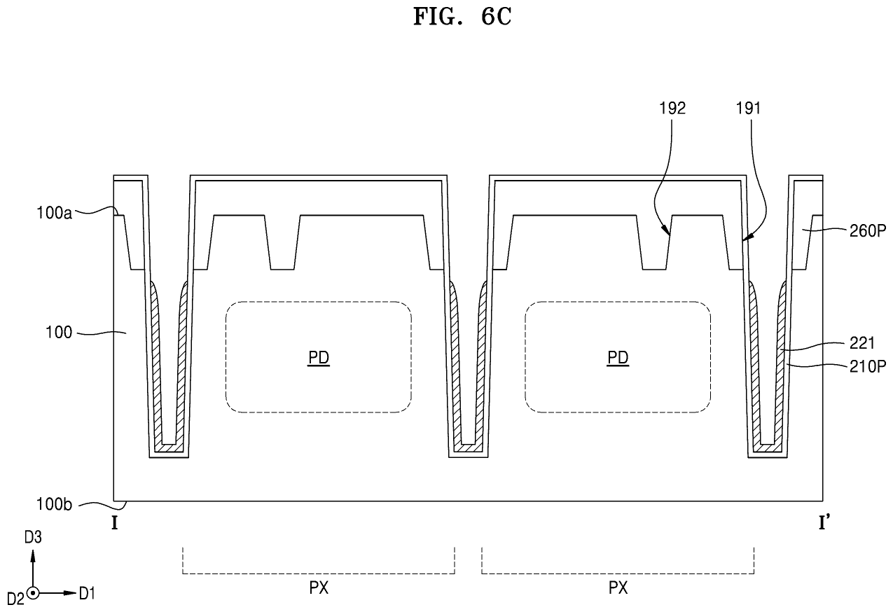

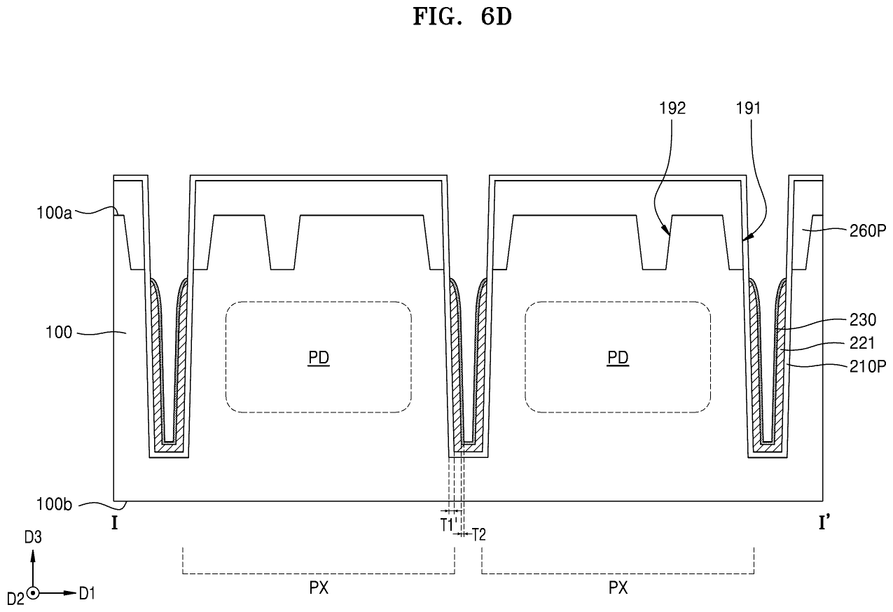

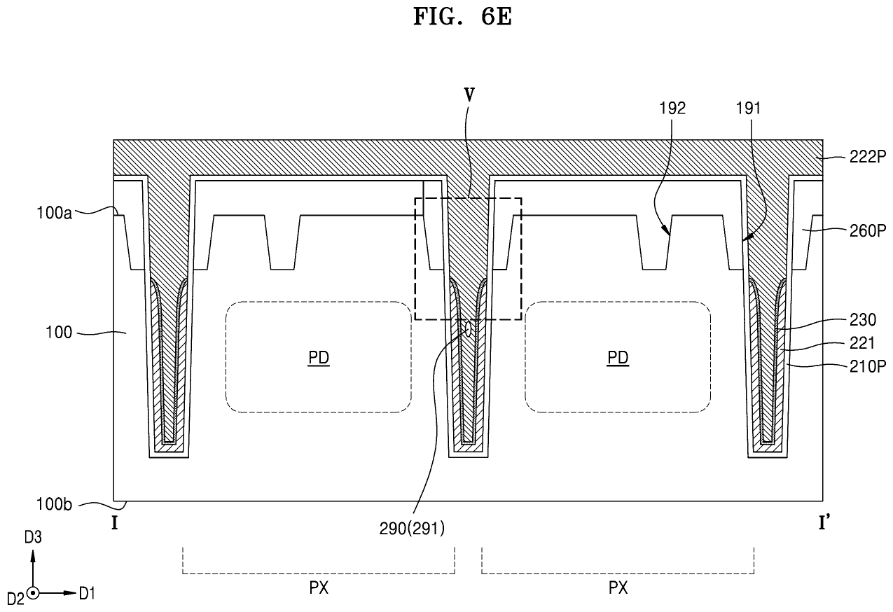

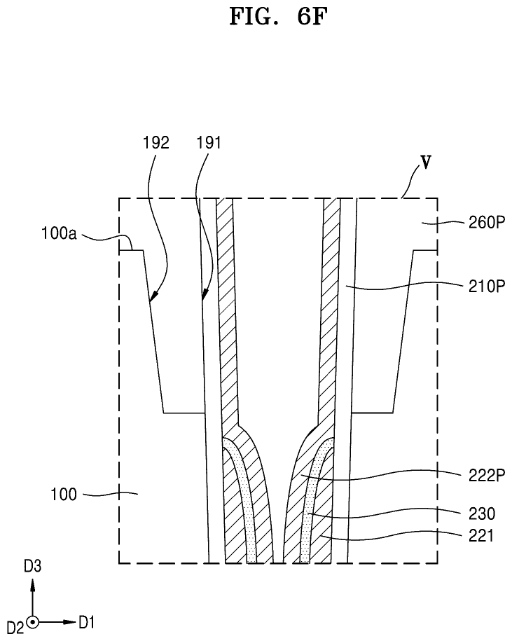

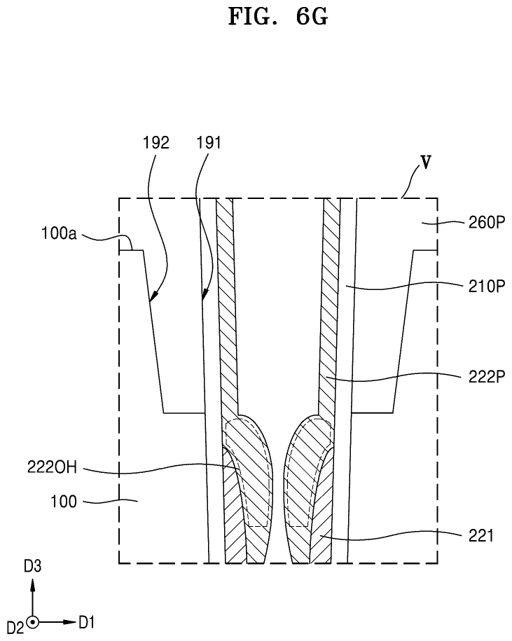

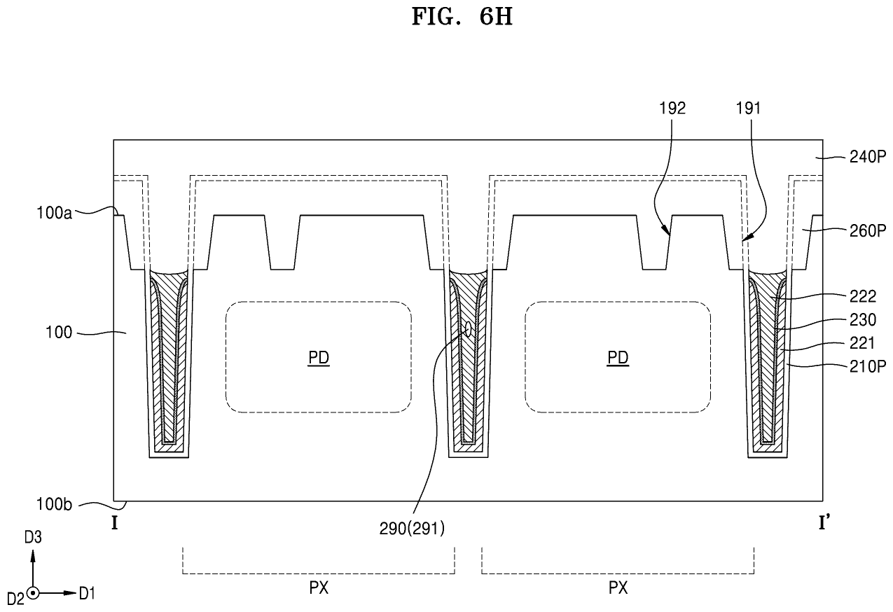

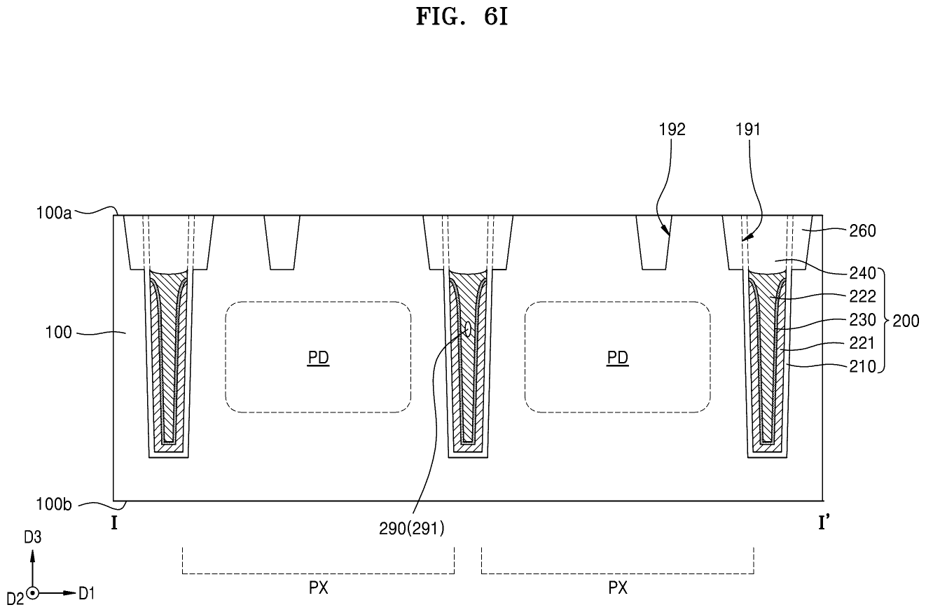

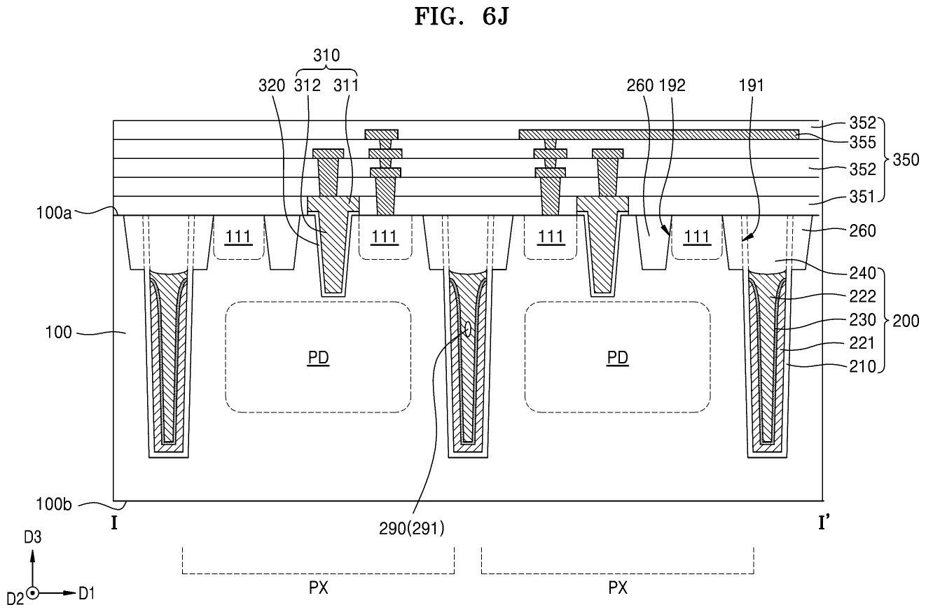

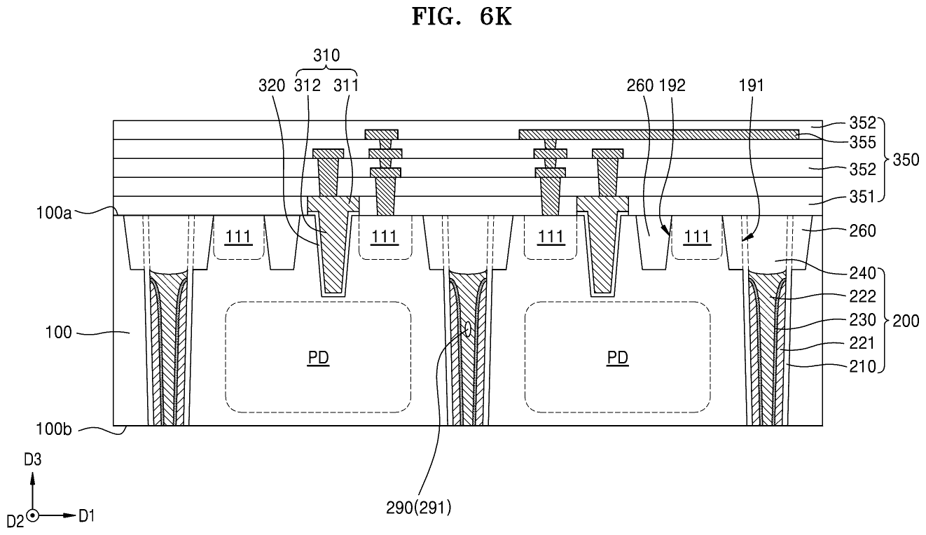

FIGS. 6A to 6K are diagrams of an example of a method of manufacturing an image sensor. FIG. 6F is a diagram for explaining a process of forming a second preliminary pattern and corresponds to an enlarged diagram of a region V of FIG. 6E. FIG. 6G is a diagram of a process of forming a second preliminary pattern when an isolation film is omitted. Hereinafter, a repeated explanation of the above description will not be given. In the description of a manufacturing example of an image sensor, a pixel region may be interpreted as including a region in which the pixel described with reference to FIG. 1 is formed and a region for forming the pixel.

Referring to FIG. 6A, the substrate 100 having the first surface 100a and the second surface 100b facing each other may be prepared. The photoelectric conversion regions PD may be respectively formed in the pixel regions PX within the substrate 100. The second trench 192 may be formed on the first surface 100a of the substrate 100. Formation of the second trench 192 may be performed through an etching process using a mask film.

A preliminary device isolation pattern 260P may be formed in the second trench 192 and on the first surface 100a of the substrate 100. The preliminary device isolation pattern 260P may fill the second trench 192.

Referring to FIG. 6B, the first trench 191 may be formed between the pixel regions PX within the substrate 100. Forming the first trench 191 may include performing an etching process on the first surface 100a of the substrate 100. The first trench 191 may be formed deeper than the second trench 192. For example, the bottom surface of the first trench 191 may be located at a lower level than the bottom surface of the second trench 192. A portion of the first trench 191 may be formed to pass through the preliminary device isolation pattern 260P. In this case, a lower portion of the sidewall of the first trench 191 may expose the substrate 100, and an upper portion of the sidewall of the first trench 191 may expose the preliminary device isolation pattern 260P. Interface defects may be formed on the bottom surface and sidewall of the first trench 191 through an etching process.

A first cleaning process may further be performed on the first surface 100a of the substrate 100 and in the first trench 191. Residues from the etching process may be removed through the first cleaning process. After the first cleaning process, an impurity injection process may be performed on the first surface 100a of the substrate 100. The doped region 120 described in FIG. 2C may be formed in the substrate 100 through the impurity injection process. The doped region may be adjacent to the sidewall of the first trench 191. Although not shown, the doped region may be further formed in a region adjacent to the bottom surface of the first trench 191 within the substrate 100. In this case, the doped region may be in contact with the bottom surface of the first trench 191. After the impurity injection process, a second cleaning process may further be performed on the first surface 100a of the substrate 100 and in the first trench 191.

Referring to FIG. 6C, a preliminary liner film 210P may be formed on the sidewall and bottom surface of the first trench 191 to cover the sidewalls and bottom surface of the first trench 191. The preliminary liner film 210P may further cover the first surface 100a of the substrate 100. Forming the preliminary liner film 210P may be performed through a deposition process. As another example, forming the preliminary liner film 210P may be performed through an oxidation process. For example, a portion of the substrate 100, which is exposed through the first trench 191, may be oxidized to form the preliminary liner film 210P.

The first pattern 221 may be formed on the preliminary liner film 210P. For example, the deposition process may be performed on the preliminary liner film 210P to form a first preliminary pattern. The deposition process may be performed under a first temperature condition. A first temperature may be about 400° C. to about 550° C. The deposition process may be performed once or multiple times. The first preliminary pattern may cover the preliminary liner film 210P on the bottom surface of the first trench 191, the sidewalls of the first trench 191, and the first surface 100a of the substrate 100. An etching process may be performed on the first preliminary pattern to form the first pattern 221. An upper portion of the first preliminary pattern may be removed through the etching process. Accordingly, the first pattern 221 may not extend onto the first surface 100a of the substrate 100. The first pattern 221 may expose upper portions of the inner sidewalls of the preliminary liner film 210P. The first pattern 221 may include an amorphous semiconductor material but is not limited thereto. For example, the first pattern 221 may include amorphous silicon.

As an example, the deposition process may include depositing a semiconductor material including a first dopant. In this case, the first pattern 221 may include a first dopant 221Z (in FIG. 2D).

As another example, after the deposition process, the first preliminary pattern may not include the first dopant. After the etching process of the first preliminary pattern, a doping process may be performed on the first pattern 221. Accordingly, the first pattern 221 may include the first dopant 221Z (in FIG. 2D). In this case, after the doping process, an additional cleaning process may be further performed.

Referring to FIG. 6D, the isolation film 230 may be formed on the first pattern 221. For example, forming the isolation film 230 may include performing an oxidation process on the first pattern 221. The oxidation process may include supplying oxygen or ozone to the first pattern 221. Accordingly, the first pattern 221 may be oxidized to form the isolation film 230. The isolation film 230 may include an oxide film. The isolation film 230 may be formed through an oxidation process, and the thickness T2 of the isolation film 230 may be about 6 Å to about 15 Å. Forming a natural oxide film with a thickness of 6 Å or more can generally be difficult. The natural oxide film may expose an underlying film. In some implementations, the isolation film 230 may continuously extend on the inner sidewalls of the first pattern 221. Exposure of the first pattern 221 may be prevented by the isolation film 230. The isolation film 230 may be formed by a different method or under a different process condition from the preliminary liner film 210P, the thickness T2 of the isolation film 230 may be less than a thickness T1′ of the preliminary liner film 210P. A thickness T1′ of the preliminary liner film 210P may be substantially the same as the thickness T1 of the liner film 210 of FIG. 2C.

The isolation film 230 includes a material different from that of the first pattern 221, and thus the first isolation film 230 may have characteristics different from those of the first pattern 221. For example, a planar density of the isolation film 230 may be greater than a planar density of the first pattern 221.

When the first pattern 221 includes an undoped semiconductor material, an impurity injection process may be performed on the isolation film 230. In this case, the doping process described in the example of FIG. 6C may be omitted. As a result of the impurity injection process, the first pattern 221 may include the first dopant 221Z (in FIG. 2D), and the isolation film 230 may include the first additional element 230Z (in FIG. 2D). The injection process of the first additional element 230Z (in FIG. 2D) may be performed in a single process with the injection process of the first dopant 221Z (in FIG. 2D). As described in FIG. 2D, the first additional element 230Z may include the same element as the first dopant 221Z. After the impurity injection process, a cleaning process may be further performed.

Referring to FIGS. 6E and 6F, a second preliminary pattern 222P may be formed on the isolation film 230. The second preliminary pattern 222P may be formed in the first trench 191 and on the first surface 100a of the substrate 100 to cover the isolation film 230 and the preliminary liner film 210P. The second preliminary pattern 222P may fill a gap between opposing inner sidewalls of the isolation film 230. The second preliminary pattern 222P may be in physical contact with the isolation film 230 and the preliminary liner film 210P.

Forming the second preliminary pattern 222P may include performing a deposition process. The deposition process may include, for example, a low pressure chemical vapor deposition process. The deposition process may be performed under a second temperature condition. The second temperature may be higher than the first temperature in FIG. 6C. For example, the second temperature may be about 570° C. to about 670° C. Due to the deposition process conditions, the second preliminary pattern 222P may have a crystalline structure.

Referring to FIG. 6G, when the isolation film 230 is omitted, the second preliminary pattern 222P may be formed on the first pattern 221 and the preliminary liner film 210P. The second preliminary pattern 222P may directly contact the inner sidewall of the first pattern 221. The second preliminary pattern 222P may directly contact an upper portion of the inner sidewall of the preliminary liner film 210P. The first pattern 221 may include a material different from that of the preliminary liner film 210P. A planar density of the preliminary liner film 210P may be a less than a planar density of the first pattern 221. Accordingly, in the deposition process, a deposition rate of the second preliminary pattern 222P on the preliminary liner film 210P may be higher than a deposition rate of the second preliminary pattern 222P on the first pattern 221. Accordingly, overhang portions 2220H of the second preliminary pattern 222P on upper portions of the inner sidewalls of the first pattern 221 may be formed to be relatively thick. Accordingly, after the deposition process is completed, a relatively large void 290 may be formed in the second preliminary pattern 222P.

Referring back to FIG. 6F, the isolation film 230 may be provided on the first pattern 221 such that the first pattern 221 is not exposed. The planar density of the isolation film 230 may be the same or similar to that of the preliminary liner film 210P. Accordingly, an incubation time of the second preliminary pattern 222P on the isolation film 230 may be the same or similar to an incubation time of the second preliminary pattern 222P on the preliminary liner film 210P. A deposition rate of the second preliminary pattern 222P on the isolation film 230 may be the same or similar to a deposition rate of the second preliminary pattern 222P on the preliminary liner film 210P. Accordingly, the formation of voids 290 may be prevented. Alternatively, the void 290 may be formed with less than a predetermined size.

Referring to FIG. 6H, an upper portion of the second preliminary pattern 222P may be removed to form the second pattern 222. The second pattern 222 may be localized in the first trench 191. Removing the upper portion of the second preliminary pattern 222P may be performed by an etching process such as wet etching. As a result of the etching process, the upper surface of the second pattern 222 may be provided at a lower level than the first surface 100a of the substrate 100. A portion of the preliminary liner film 210P on the first surface 100a of the substrate 100 may be exposed. Upper portions of inner sidewalls of the preliminary liner film 210P in the first trench 191 may be exposed.

A preliminary capping pattern 240P may be formed in the first trench 191 to cover an upper surface of the second pattern 222 and upper portions of the inner sidewalls of the preliminary liner film 210P. The preliminary capping pattern 240P may fill the first trench 191. The preliminary capping pattern 240P may be formed on the first surface 100a of the substrate 100 to cover the upper surface of the preliminary liner film 210P. Forming the preliminary capping pattern 240P may be performed through a deposition process.

Referring to FIGS. 6H and 6I, a planarization process may be performed on the preliminary capping pattern 240P and the preliminary liner film 210P to form the capping pattern 240 and the liner film 210. Through the planarization process, the upper portion of the preliminary capping pattern 240P may be removed to form the capping pattern 240. The capping pattern 240 may be localized in the first trench 191. Through the planarization process, the upper portion of the preliminary liner film 210P may be removed to form the liner film 210. The liner film 210 may be localized in the first trench 191. The liner film 210 and the capping pattern 240 may not extend onto the first surface 100a of the substrate 100. Accordingly, the deep isolation pattern 200 may be formed in the first trench 191. The deep isolation pattern 200 may include the liner film 210, the first pattern 221, the second pattern 222, the isolation film 230, and the capping pattern 240.

The planarization process may be performed on the preliminary device isolation pattern 260P, thereby forming the device isolation pattern 260. For example, an upper portion of the isolation film 230 may be removed to form the device isolation pattern 260. The device isolation pattern 260 may be localized in the second trench 192. As a result of the planarization process, the first surface 100a of the substrate 100 may be exposed. The device isolation pattern 260 may not extend onto the first surface 100a of the substrate 100.

Referring to FIG. 6J, the gate insulating pattern 320 and the gate pattern 310 may be formed on the first surface 100a of the substrate 100. The gate insulating pattern 320 and gate pattern 310 may extend further into the substrate 100. Second conductive type impurities may be injected into the substrate 100 to form the impurity regions 111.

The first insulating layer 351, the second insulating layers 352, and the conductive structures 355 may be formed on the first surface 100a of the substrate 100 to form the wiring layer 350. One of the conductive structures 355 may be electrically connected to one corresponding impurity region 111, and the other of the conductive structures 355 may be electrically connected to the gate pattern 310.

Even if the first pattern 221 of FIG. 2B includes an amorphous semiconductor material, after forming the conductive structures 355, the first pattern 221 may have a crystalline structure. Heat may be applied to an isolation pattern during a formation process of the gate pattern 310 or a formation process of the conductive structures 355. The first pattern 221 may be crystallized by the heat.

When the second pattern 222 is in direct physical contact with the first pattern 221, as a result of the crystallization process of the first pattern 221, a grain size of the first pattern 221 may be the same as the size of the second pattern 222. In some implementations, the isolation film 230 is provided, and thus a grain size of the second pattern 222 may be greater than a grain size of the first pattern 221.

Referring to FIG. 6K, a thinning process may be performed on the second surface 100b of the substrate 100 to expose the deep isolation pattern 200 on the second surface 100b of the substrate 100. In the thinning process, a bottom portion of the liner film 210 may be removed, exposing the liner film 210 and the first pattern 221 on the second surface 100b of the substrate 100. A bottom portion of the first pattern 221 may be further removed, exposing the isolation film 230 and the second pattern 222 on the second surface 100b of the substrate 100. That is, the liner film 210, the first pattern 221, the second pattern 222, and the isolation film 230 may be exposed on the second surface 100b of the substrate 100. Alternatively, at least one of the liner film 210, the first pattern 221, the second pattern 222, and the isolation film 230 may not be exposed on the second surface 100b of the substrate 100. The thinning process may be performed by an etch-back process or a chemical mechanical polishing (CMP) process.

Referring back to FIG. 2A, the back surface insulating layer 500, the grid pattern 550, the protective film 510, the color filters CF, and the microlens patterns 600 may be formed on the second surface 100b of the substrate 100. The image sensor 1 described in FIG. 2A may be manufactured using the examples described thus far.

Heat may be applied into the deep isolation pattern 200 during the manufacturing process of the image sensor. The manufacturing process may include a subsequent process of forming the deep isolation pattern 200. For example, the subsequent process may include, but is not limited to, a formation process of the wiring layer 350 or a formation process of the gate pattern 310 in FIG. 6J. A material of the void 290 or the second pattern 222 may move due to the heat applied in the subsequent process.

For example, as shown in FIG. 2A, a plurality of first voids 291 in the first region RI or the second region R2 may move to the cross region CR and may be combined with each other to form the second void 292. Accordingly, the size of the second void 292 in the cross region CR may be increased. The second void 292 may have a relatively large size. When the second pattern 222 is in direct contact with the first pattern 221, the void 290 in the second pattern 222 may move together with a semiconductor material in the first patterns 221. For example, the void 290 may extend into the first pattern 221. Accordingly, the void 290 may be formed larger than a predetermined size.

In some implementations, the isolation film 230 may be further located between the first pattern 221 and the second pattern 222. The isolation film 230 may function as a barrier film and may prevent migration of the void 290. Accordingly, it may be difficult for the void 290 to migrate or expand into the isolation film 230 or the first pattern 221. Accordingly, the void 290 may be formed less than a predetermined size. The image sensor 1 may have improved image characteristics and improved intensity.

Advantageously, the isolation pattern may include a liner film, a first pattern, a second pattern, and an isolation film. The isolation film may be provided between the first pattern and the second pattern. The isolation pattern may include the isolation film, and thus the image sensor may have improved image characteristics and increased intensity.

The detailed description of the inventive concept above is not intended to limit the inventive concept to the disclosed embodiments, and may be used in various other combinations, changes, and environments without departing from the gist of the inventive concept. The appended claims should be construed to include other embodiments as well.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the inventive concept has been particularly shown and described with reference to embodiments thereof, it will be understood that various changes in form and details may be made therein without departing from the spirit and scope of the following claims.

What is claimed is:

1. An image sensor comprising:
a substrate having photoelectric conversion regions; and
a deep isolation pattern provided between the photoelectric conversion regions within the substrate, wherein the deep isolation pattern includes:
a liner film covering a sidewall of a trench in the substrate;
a first pattern provided on an inner sidewall of the liner film and having a height less than a height of the liner film;
an isolation film on inner sidewalls of the first pattern; and
a second pattern covering inner sidewalls of the isolation film and an upper portion of the inner sidewall of the liner film,
wherein a void is provided in the second pattern,
wherein the second pattern is spaced apart from the first pattern by the isolation film, and
wherein a grain size of the second pattern is larger than a grain size of the first pattern.

2. The image sensor of claim 1, wherein the isolation film comprises a material different from materials of the first pattern and the second pattern, and
wherein a first additional element provided in the isolation film comprises a same element as a first dopant in the first pattern.

3. The image sensor of claim 1, wherein the isolation film comprises a same material as that of the liner film.

4. The image sensor of claim 1, wherein a thickness of the liner film in a first direction at a point between a first surface of the substrate and a second surface of the substrate is greater than a thickness of the isolation film, and
wherein the first direction is parallel to the first surface of the substrate.

5. The image sensor of claim 1, wherein the isolation film continuously extends along the inner sidewalls of the first pattern,
wherein the inner sidewall of the first pattern is spaced apart from the second pattern in a first direction at a point between a first surface of the substrate and a second surface of the substrate, and
wherein the first direction is parallel to the first surface of the substrate.

6. The image sensor of claim 1, wherein, in terms of a plan view, the deep isolation pattern includes:
a first region extending in a first direction;
a second region extending in a second direction intersecting with the first direction; and
a cross region provided at a portion in which the first region and the second region intersect with each other,
wherein the void includes:
a first void in the cross region; and
a second void in at least one of the first region and the second region.

7. The image sensor of claim 6, wherein a cross-sectional area of the second void is larger than a cross-sectional area of the first void.

8. The image sensor of claim 1, wherein the void is spaced apart from the first pattern, and
wherein the isolation film is located between the void and the first pattern.

9. The image sensor of claim 1, further comprising:
a gate pattern on a first surface of the substrate; and
a shallow insulation pattern provided between the deep isolation pattern and the first surface of the substrate,
wherein an upper surface of the shallow insulation pattern further includes at least one of a protrusion and a recess.

10. The image sensor of claim 1, wherein the isolation film has a thickness between 6 Å to 15 Å in a first direction at a point between a first surface of the substrate and a second surface of the substrate, and
wherein the first direction is parallel to the first surface of the substrate.

11. An image sensor comprising:
a substrate having a first surface and a second surface that face each other; and
a deep isolation pattern defining photoelectric conversion regions in the substrate, wherein the deep isolation pattern includes:
a liner film covering a sidewall of a trench in the substrate;
a first pattern on an inner sidewall of the liner film;
a second pattern provided on the first pattern; and
an isolation film between the first pattern and the second pattern,
wherein the second pattern is spaced apart from the first pattern by the isolation film,
wherein the isolation film comprises a material different from that of the first pattern, and
wherein a first additional element provided in the isolation film comprises a same element as a first dopant in the first pattern.

12. The image sensor of claim 11, wherein the isolation film includes a first portion and a second portion,
wherein the first portion of the isolation film is provided between the first pattern and the second portion, and
wherein a concentration of the first additional element in the first portion of the isolation film is greater than a concentration of the first additional element in the second portion.

13. The image sensor of claim 11, wherein a crystal orientation of the second pattern is different from a crystal orientation of the first pattern.

14. The image sensor of claim 11, wherein the first pattern exposes an upper portion of the inner sidewall of the liner film,
wherein the second pattern is provided between inner sidewalls of the isolation film, and
wherein the second pattern directly contacts the inner sidewalls of the first pattern and the upper portion of the inner sidewall of the liner film.

15. The image sensor of claim 11, wherein the liner film comprises a material different from that of the first pattern, and
wherein a second additional element provided in the liner film comprises a same element as the first dopant.

16. The image sensor of claim 11, wherein the first additional element comprises boron.

17. An image sensor comprising:
a substrate having a first surface, a second surface facing the first surface, and a plurality of photoelectric conversion regions;
photoelectric conversion regions provided between the first surface and the second surface of the substrate;
a deep isolation pattern provided within the substrate and between the photoelectric conversion regions;
impurity regions located within the substrate and located adjacent to the first surface of the substrate;
a gate pattern disposed on the first surface of the substrate;
a wiring layer disposed on the first surface of the substrate and including insulating layers and a conductive structure;
color filters disposed on the second surface of the substrate;
a grid pattern located between the color filters; and
a microlens pattern disposed on the color filters,
wherein the deep isolation pattern includes:
a liner film covering a sidewall of a trench in the substrate;
a first pattern provided on an inner sidewall of the liner film and having a height less than a height of the liner film;
an isolation film on inner sidewalls of the first pattern; and
a second pattern covering inner sidewalls of the isolation film and an upper portion of the inner sidewall of the liner film,
wherein a void is provided in the second pattern,
wherein the second pattern is spaced apart from the first pattern by the isolation film,
wherein the isolation film includes a material different from the first pattern and the second pattern, and
wherein a first additional element provided in the isolation film comprises a same element as a first dopant in the first pattern.

18. The image sensor of claim 17, wherein a grain size of the second pattern is larger than a grain size of the first pattern.

19. The image sensor of claim 17, wherein the trench is formed to pass through at least one of the first surface and the second surface of the substrate.

20. The image sensor of claim 17, wherein one color filter of the color filters overlaps the plurality of photoelectric conversion regions.
